(19) United States
(12) Patent Application Publication
(10) Pub. No.: US 2024/0321941 A1
(43) Pub. Date: Sep. 26, 2024

(54) INTEGRATED CIRCUIT SEMICONDUCTOR DEVICE

(71) Applicant: Samsung Electronics Co., Ltd., Suwon-si (KR)

(72) Inventors: Intak JEON, Suwon-si (KR); Beomjong KIM, Suwon-si (KR)

(73) Assignee: Samsung Electronics Co., Ltd., Suwon-si (KR)

(21) Appl. No.: 18/581,664

(22) Filed: Feb. 20, 2024

(30) Foreign Application Priority Data
Mar. 24, 2023 (KR) 10-2023-0039107
Apr. 10, 2023 (KR) 10-2023-0046936

(51) Int. Cl. H10B 12/00

(52) U.S. Cl. CPC H01L 28/60; H10B 12/30

(57) ABSTRACT

An integrated circuit semiconductor device includes lower electrodes on a substrate, and a support structure supporting the lower electrodes around the lower electrodes. The support structure includes a first support structure supporting lower portions of the lower electrodes, a second support structure apart from the first support structure in a vertical direction perpendicular to the substrate and supporting middle portions of the lower electrodes, and a third support structure apart from the second support structure in the vertical direction perpendicular to the substrate and supporting node portions of the lower electrodes. Each of the first support structure, the second support structure, and the third support structure includes a support pattern and additional holes formed through the support pattern. The support pattern extends in a horizontal direction parallel to the substrate and surrounds the lower electrodes. The support pattern includes holes through which the lower electrodes pass.

### CROSS-REFERENCE TO RELATED APPLICATION

This application is based on and claims priority under 35 U.S.C. § 119 to Korean Patent Application No. 10-2023-0039107, filed on Mar. 24, 2023, in the Korean Intellectual Property Office, and Korean Patent Application No. 10-2023-0046936, filed on Apr. 10, 2023, in the Korean Intellectual Property Office, the disclosures of which are incorporated by reference herein in their entireties.

### BACKGROUND

The inventive concepts relate to integrated circuit semiconductor devices. More particularly, the inventive concepts relates to integrated circuit semiconductor devices including a capacitor.

Integrated circuit semiconductor devices have been rapidly scaled down owing to the development of electronics, and thus, the sizes of patterns of integrated circuit semiconductor devices have been reduced. Therefore, it is needed to develop a structure for improving the capacitance of fine capacitors while maintaining desired electrical characteristics of the fine capacitors.

### SUMMARY

The inventive concepts provide integrated circuit semiconductor devices configured to prevent or reduce lower electrodes forming capacitors from leaning or breaking even when the lower electrodes have a large height.

The inventive concepts are not limited thereto, and the inventive concepts will be apparently understood by those skilled in the art through the following description.

According to aspects of the inventive concepts, integrated circuit semiconductor devices are provided as follows.

According to some aspects of the inventive concepts, there is provided an integrated circuit semiconductor device. The integrated circuit semiconductor device includes lower electrodes on a substrate, and a support structure supporting the lower electrodes around the lower electrodes. The support structure includes a first support structure supporting lower portions of the lower electrodes, a second support structure apart from the first support structure in a vertical direction perpendicular to the substrate and supporting middle portions of the lower electrodes, and a third support structure apart from the second support structure in the vertical direction perpendicular to the substrate and supporting node portions of the lower electrodes. Each of the first support structure, the second support structure, and the third support structure includes a support pattern and additional holes formed through the support pattern. The support pattern extends in a horizontal direction parallel to the substrate and surrounds the lower electrodes. The support pattern includes holes through which the lower electrodes pass.

According to some aspects of the inventive concepts, there is provided an integrated circuit semiconductor device. The integrated circuit semiconductor device includes lower electrodes on a substrate, and a support structure supporting the lower electrodes around the lower electrodes. The support structure includes a first support structure supporting lower portions of the lower electrodes, a second support structure apart from the first support structure in a vertical direction perpendicular to the substrate and supporting middle portions of the lower electrodes, and third support structures apart from the second support structure in the vertical direction perpendicular to the substrate and formed in a spherical shape on upper node portions of the lower electrodes. Each of the first support structure and the second support structure includes a support pattern and additional holes formed through the support pattern. The support pattern extends in a horizontal direction parallel to the substrate and surrounds the lower electrodes. The support pattern includes holes through which the lower electrodes pass.

According to some aspects of the inventive concepts, there is provided an integrated circuit semiconductor device. The integrated circuit semiconductor device includes a plurality of lower electrodes, a third support structure, a second support structure, a first support structure, a dielectric layer, and an upper electrode. The plurality of lower electrodes are arranged apart from each other on a substrate. The third support structure is at nodes of the plurality of lower electrodes in a horizontal direction parallel to the substrate. The second support structure includes a second support pattern extending in the horizontal direction parallel to the substrate. The second support pattern includes a plurality of holes through which the plurality of lower electrodes pass and has a flat surface parallel to the substrate. The first support structure includes a first support pattern extending in the horizontal direction between the substrate and the second support structure. The first support pattern includes a plurality of holes through which the plurality of lower electrodes pass and has a flat surface parallel to the substrate. The dielectric layer is in contact with the plurality of lower electrodes, the first support structure, and the second support structure. The upper electrode faces the plurality of lower electrodes with the dielectric layer therebetween.

### BRIEF DESCRIPTION OF THE DRAWINGS

Embodiments will be more clearly understood from the following detailed description taken in conjunction with the accompanying drawings in which:

FIG. 1 is a schematic plan layout illustrating some elements in a memory cell array region of an integrated circuit semiconductor device according to some example embodiments;

FIG. 2 is a plan view illustrating some elements of an integrated circuit semiconductor device according to some example embodiments;

FIGS. 3A and 3B are schematic cross-sectional views taken along line X-X′ of FIG. 2 to illustrate some elements of the integrated circuit semiconductor device;

FIGS. 4A to 4G are cross-sectional views illustrating a method of fabricating the integrated circuit semiconductor device shown in FIG. 3A, according to some example embodiments;

FIG. 5 is a plan view illustrating a memory module including an integrated circuit semiconductor device, according to some example embodiments;

FIG. 6 is a schematic view illustrating a memory card including an integrated circuit semiconductor device, according to some example embodiments; and

FIG. 7 is a schematic view illustrating a system including an integrated circuit semiconductor device, according to some example embodiments.

### DETAILED DESCRIPTION

Hereinafter, example embodiments will be described with reference to the accompanying drawings. In the drawings, like reference numerals denote like elements, and repeated descriptions thereof are omitted.

The inventive concepts may be embodied in various different forms and various embodiments, and some example embodiments are described with reference to the accompanying drawings. However, the inventive concepts are not limited to the example embodiments, and it should be understood that the idea and technical scope of example embodiments cover all the modifications, equivalents, and replacements. Detailed descriptions related to well-known functions or configurations may be ruled out in order not to unnecessarily obscure subject matters of the inventive concepts.

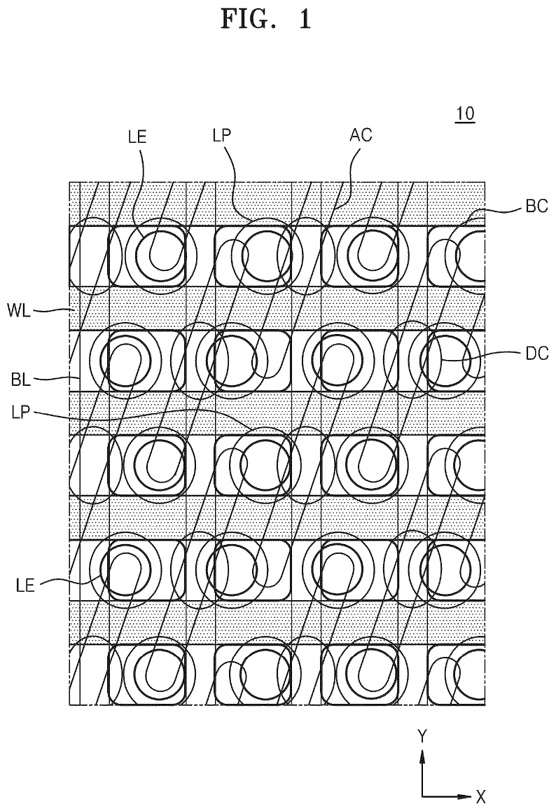

FIG. 1 is a schematic plan layout illustrating some elements in a memory cell array region of an integrated circuit semiconductor device 10 according to some example embodiments.

The integrated circuit semiconductor device 10 (for example, a dynamic random access memory (DRAM) device) may include a plurality of active regions AC horizontally extending on a plane in an oblique direction with respect to X and Y directions. A plurality of word lines WL may extend parallel to each other in the X direction across the plurality of active regions AC. A plurality of bit lines BL may extend above the plurality of word lines WL in parallel to each other in the Y direction crossing the X direction. The bit lines BL may extend to the active regions AC through direct contacts DC.

A plurality of buried contacts BC may be formed between two adjacent bit lines BL among the bit lines BL. A plurality of conductive landing pads LP may be formed on the buried contacts BC. At least a portion of each of the conductive landing pads LP may overlap a buried contact BC. A plurality of lower electrodes LE may be formed apart from each other on the conductive landing pads LP. The lower electrodes LE may be connected to the active regions AC through the buried contacts BC and the conductive landing pads LP.

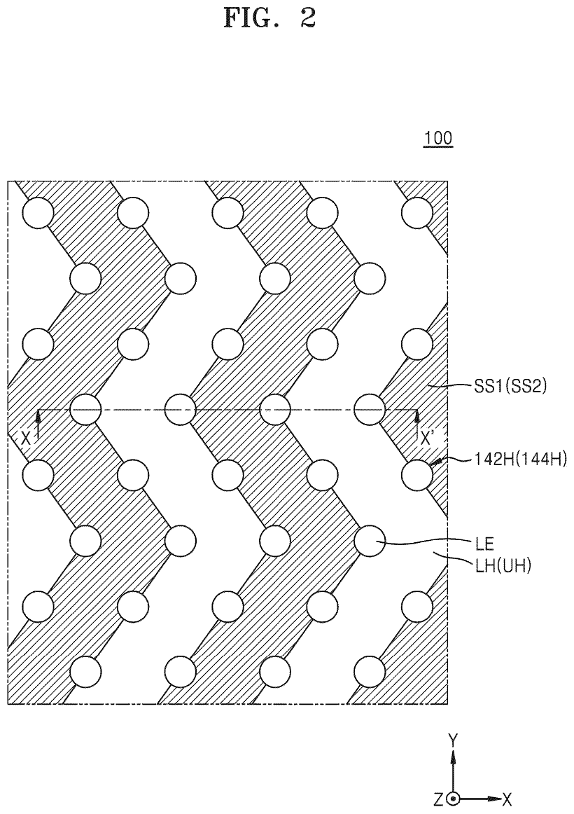

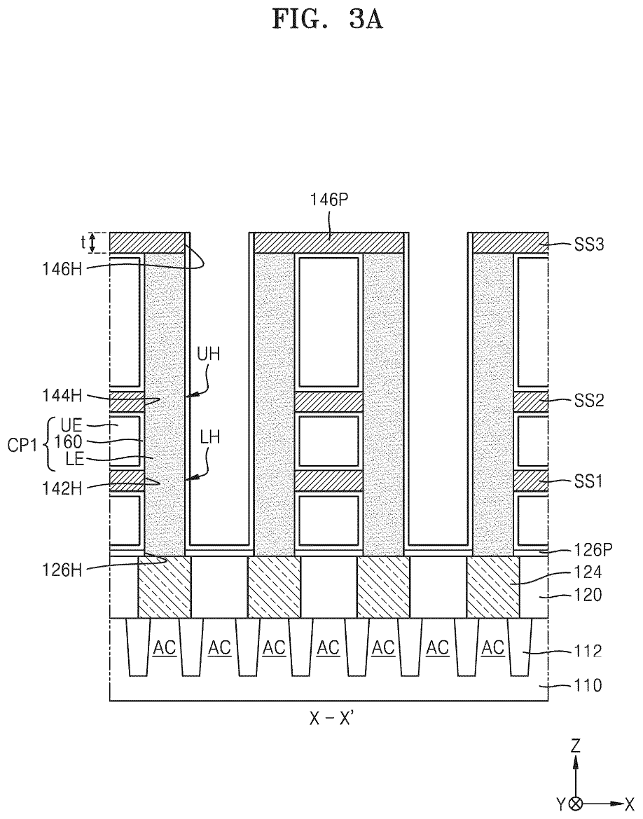

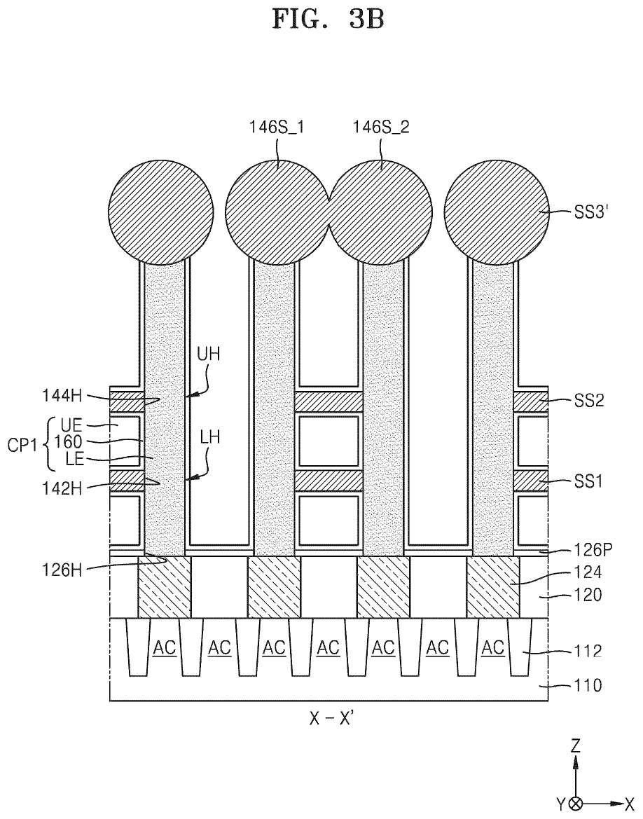

FIG. 2 is a plan view illustrating some elements of an integrated circuit semiconductor device 100 according to some example embodiments, and FIGS. 3A and 3B are schematic cross-sectional views taken along line X-X′ of FIG. 2 to illustrate some elements of the integrated circuit semiconductor device 100.

In FIGS. 2, 3A, and 3B, some elements of the integrated circuit semiconductor device 100 are omitted or simplified. However, the configuration of the integrated circuit semiconductor device 100 is not limited to those shown in FIGS. 2, 3A, and 3B, and it should be understood that the integrated circuit semiconductor device 100 includes characteristic elements as described below.

The integrated circuit semiconductor device 100 includes a substrate 110 including a plurality of active regions AC and a lower structure 120 formed on the substrate 110. A plurality of conductive regions 124 may be connected to the active regions AC through the lower structure 120.

The substrate 110 may include a semiconductor element such as Si or Ge, or a compound semiconductor such as SiC, GaAs, InAs, or InP. The substrate 110 may include a structure that includes a semiconductor substrate and at least one conductive region or at least one insulating layer formed on the semiconductor substrate. The conductive region may include, for example, a well doped with a dopant or a structure doped with a dopant. Device isolation regions 112 defining the active regions AC may be formed in the substrate 110. The device isolation regions 112 may each include an oxide layer, a nitride layer, or a combination thereof.

In some example embodiments, the lower structure 120 may include an insulating layer including a silicon oxide layer, a silicon nitride layer, or a combination thereof. In some example embodiments, the lower structure 120 may include various conductive regions such as a wiring layer, contact plugs, transistors, or the like; and an insulating layer insulating the various conductive regions from each other.

The conductive regions 124 may include polysilicon, a metal, a conductive metal nitride, a metal silicide, or a combination thereof. The lower structure 120 may include a plurality of bit lines BL as described with reference to FIG. 1. Each of the conductive regions 124 may include a buried contact BC and a conductive landing pad LP as described with reference to FIG. 1.

An insulating pattern 126P having a plurality of openings 126H may be disposed on the lower structure 120 and the conductive regions 124. The insulating pattern 126P may include a silicon nitride layer, a silicon carbonitride layer, a boron-containing silicon nitride layer, or a combination thereof. The insulating pattern 126P may include, for example, SiBN.

A plurality of capacitors CP1 including a plurality of lower electrodes LE, a dielectric layer 160 and an upper electrode UE may be disposed on the conductive regions 124. Each of the lower electrodes LE may have a pillar shape extending from an upper surface of a conductive region 124 through an opening 126H of the insulating pattern 126P in a vertical direction (Z direction) away from the substrate 110. The dielectric layer 160 and the upper electrode UE may be sequentially formed on the lower electrodes LE.

Although FIGS. 2, 3A, and 3B illustrate that each of the lower electrodes LE has a pillar shape, the inventive concepts are not limited thereto. For example, each of the lower electrodes LE may have a cross-sectional shape similar to that of a cup or a cylinder having a closed bottom. The lower electrodes LE and the upper electrode UE may face each other with the dielectric layer 160 therebetween.

Each of the lower electrodes LE and the upper electrode UE may include a metal layer, a conductive metal oxide layer, a conductive metal nitride layer, a conductive metal oxynitride layer, or a combination thereof. In some example embodiments, each of the lower electrodes LE and the upper electrode UE may include titanium (Ti), titanium oxide, titanium nitride, titanium oxynitride, cobalt (Co), cobalt oxide, cobalt nitride, cobalt oxynitride, niobium (Nb), niobium oxide, niobium nitride, niobium oxynitride, tin (Sn), tin oxide, tin nitride, tin oxynitride, or a combination thereof.

For example, each of the lower electrodes LE and the upper electrode UE may include TiN, TiSiN, or a combination thereof but is not limited thereto. The lower electrodes LE may include a material having a work function of 5.4 eV or greater. The dielectric layer 160 may include HfO₂, ZrO₂, Al₂O₃, La₂O₃, Ta₂O₃, Nb₂O₅, CeO₂, TiO₂, GeO₂, or a combination thereof but is not limited thereto.

Referring to FIG. 3A, the lower electrodes LE may be supported by a first support structure SS1, a second support structure SS3, and a third support structure SS3. The first support structure SS1 may support lower portions of the lower electrodes LE. The second support structure SS2 may be apart from the first support structure SS1 in the vertical direction perpendicular to the substrate 110 and may support middle portions of the lower electrodes LE. The third support structure SS3 may be apart from the second support structure SS2 in the vertical direction perpendicular to the substrate 110 and may support upper ends of the lower electrodes LE.

The third support structure SS3 may include an upper support pattern 146P. The upper support pattern 146P may extend in a horizontal direction parallel to the substrate 110 while enclosing an upper end of each of the lower electrodes LE at a position apart from the lower electrode LE. In some example embodiments, the upper support pattern 146P may be a structure having a size of, for example, several nanometers.

The third support structure SS3 may completely cover upper surfaces of two lower electrodes LE connected to both ends of a node.

A plurality of holes 146H through which the lower electrodes LE pass may be formed in the upper support pattern 146P.

The third support structure SS3 may have a layered structure. For example, the third support structure SS3 may have a stacked structure in which a SiCN layer and a SiN layer are sequentially stacked from below. In the stacked structure, the thickness of the SiCN layer and the thickness of the SiN layer may be the same or different from each other. For example, the third support structure SS3 may have a stacked structure in which a SiN layer and a SiCN layer are sequentially stacked from below. In the stacked structure, the thickness of the SiN layer and the thickness of the SiCN layer may be the same or different from each other.

The first support structure SS1 and the second support structure SS2 may extend between the substrate 110 and the upper support pattern 146P in the horizontal direction parallel to the substrate 110 and may be in contact with the lower electrodes LE.

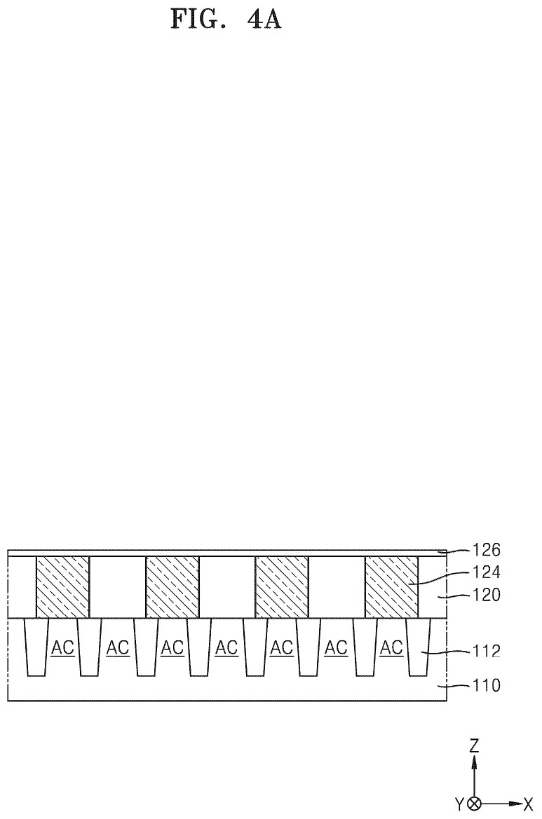

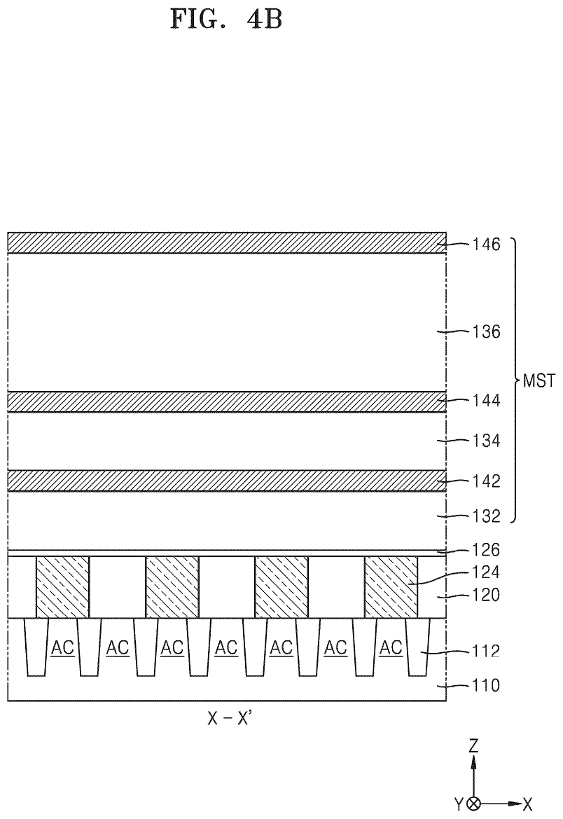

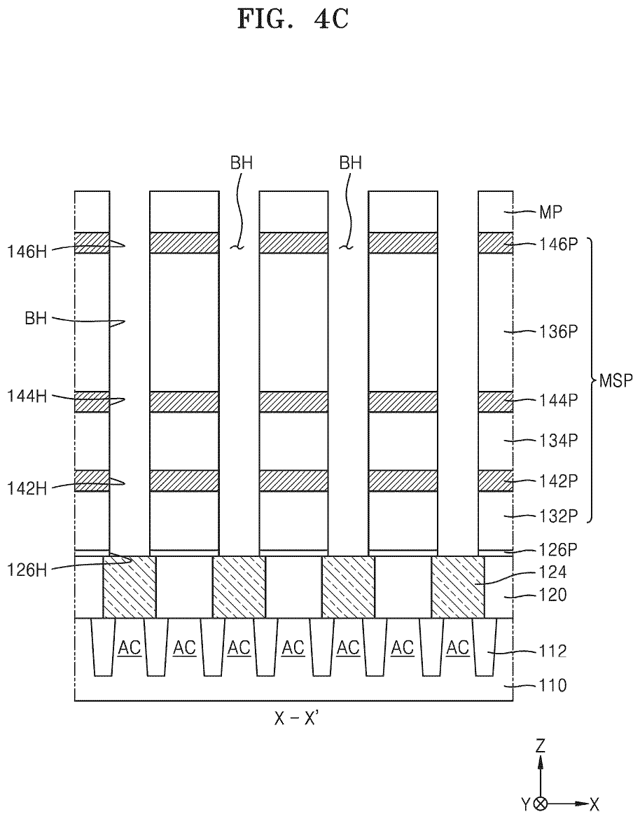

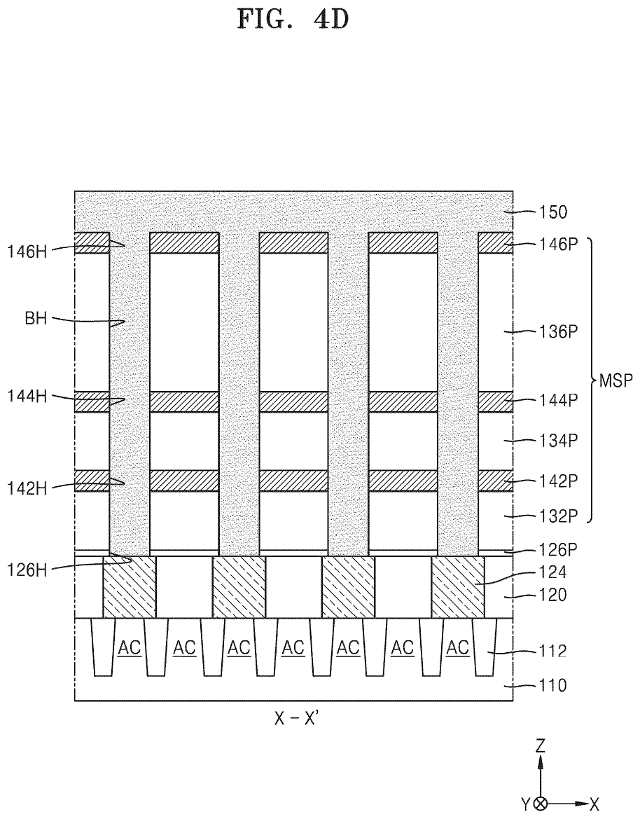

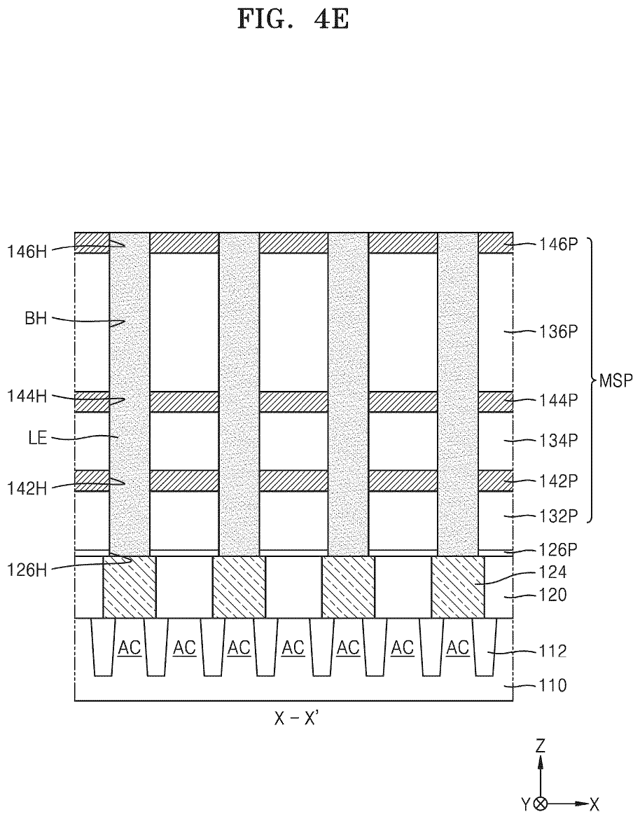

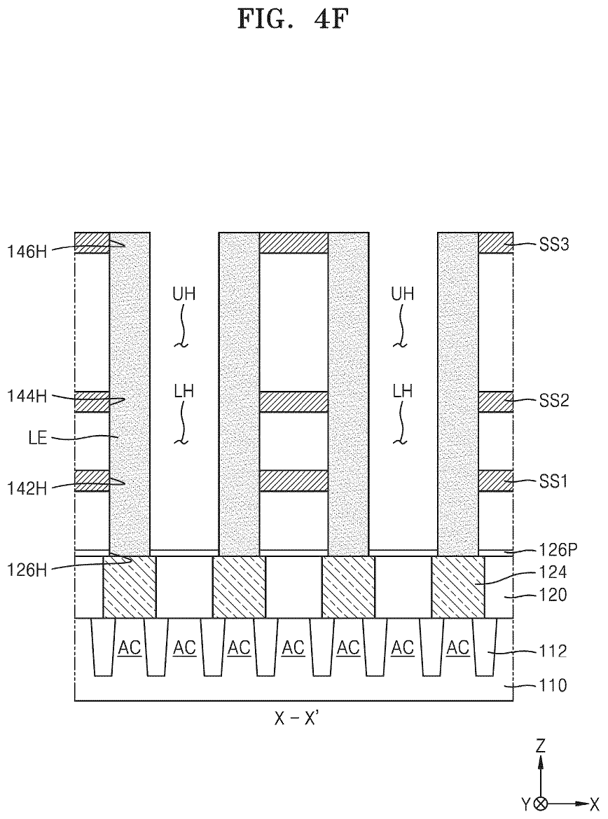

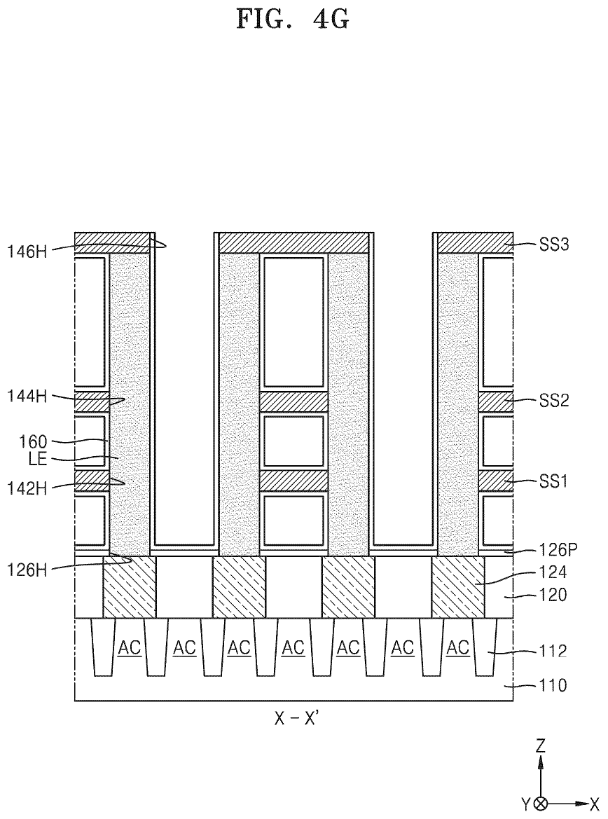

A plurality of holes 142H and a plurality of holes 144H through which the lower electrodes LE pass may be formed in a first support pattern 142P (refer to FIG. 4C) and a second support pattern 144P (refer to FIG. 4C). The lower electrodes LE may extend in the vertical direction (Z direction) through the holes 146H formed in the upper support pattern 146P, the holes 142H formed in the first support pattern 142P, and the holes 144H formed in the second support pattern 144P. In some example embodiments, the first support pattern 142P and the second support pattern 144P may be structures having a size of, for example, several nanometers.

A surface of each of the first support pattern 142P, the second support pattern 144P, and the upper support pattern 146P may include a flat surface in a direction parallel to the substrate 110.

The first support structure SS1 and the second support structure SS2 may include a silicon carbonitride layer, a boron-containing silicon nitride layer, or a combination thereof. In some example embodiments, the first support structure SS1 and the second support structure SS2 may include the same material. In some example embodiments, the first support structure SS1 and the second support structure SS2 may include the same material as a material included in the third support structure SS3. In some example embodiments, the first support structure SS1 and the second support structure SS2 may include different materials.

For example, the first support structure SS1 may include a silicon carbonitride layer and the second support structure SS2 may include a boron-containing silicon nitride layer. In embodiments, however, materials included in the first support structure SS1 and the second support structure SS2 are not limited to the materials listed above, and the first support structure SS1 and the second support structure SS2 may be variously modified and changed within the scope of the inventive concepts.

Although the integrated circuit semiconductor device 100 of the current embodiment is illustrated as having three support structures, that is, the first support structure SS1, the second support structure SS2, and the third support structure SS3, the integrated circuit semiconductor device 100 may include more support structures. In the integrated circuit semiconductor device 100 of the current embodiment, the first support structure SS1, the second support structure SS2, and the third support structure SS3 are illustrated as having the same thickness. However, in the integrated circuit semiconductor device 100, the thickness of the third support structure SS3 may be less than the thickness of the first support structure SS1 and the thickness of the second support structure SS2. In embodiments, the thicknesses of the first support structure SS1 and the second support structure SS2 are not limited.

In the integrated circuit semiconductor device 100, a space between upper portions of the lower electrodes LE may be filled with the third support structure SS3. In the integrated circuit semiconductor device 100, a space between middle portions of the lower electrodes LE may be filled with the second support structure SS2. In the integrated circuit semiconductor device 100, a space between lower portions of the lower electrodes LE may be filled with the first support structure SS1.

Referring back to FIG. 2, in the integrated circuit device 100 of the inventive concepts, a plurality of additional lower holes LH and a plurality of additional upper holes UH may be further formed between the lower electrodes LE. The holes 142H through which the lower electrodes LE pass, and the additional lower holes LH through which the lower electrodes LE pass may be formed in the first support structure SS1, that is, in the first support pattern 142P. The holes 142H and the additional lower additional holes LH may be on the same plane.

The holes 144H through which the lower electrodes LE pass and the additional upper holes UH through which the lower electrodes LE pass may be formed in the second support structure SS2, that is, the second support pattern 144P. The holes 144H and the additional upper holes UH may be on the same plane.

The additional lower and upper holes LH and UH may cross each other between the lower electrodes LE. The accompanying drawings of the present specification illustrate only the case in which the additional upper and lower holes LH and UH cross each other between the lower electrodes LE. However, the additional lower and upper holes LH and UH are not required to cross each at each node, and the inventive concepts are not limited thereto.

When the integrated circuit semiconductor device 100 further includes the additional lower and upper holes LH and UH, the first support structure SS1 and the second support structure SS2 may support not all of the lower electrodes LE.

In some example embodiments, the first support pattern 142P, the second support pattern 144P, and the upper support pattern 146P may be respectively obtained by performing a lithography process on the first support structure SS1, the second support structure SS2, and the third support structure SS3. The lithography process may be a photolithography process using a photoresist or may be a block copolymer lithography process using a block copolymer.

FIG. 2 illustrates an example in which the holes 142H (144H) are arranged in zigzags along which approximately rhombic planar shapes each having vertices formed by four adjacent lower electrodes LE are continuously connected to each other. However, the inventive concepts are not limited to the example shown in FIG. 2, and various modifications and changes may be made within the scope of the inventive concepts.

FIG. 3B is a schematic cross-sectional view taken along line X-X′ of FIG. 2 to illustrate other elements of the integrated circuit semiconductor device 100. In the following description of FIG. 3B, those described with reference to FIG. 3A are not described in detail, and differences from those described with reference to FIG. 3A are mainly described.

Referring to FIG. 3B, a third support structure SS3′ having a spherical shape may be formed on upper node portions of the lower electrodes LE. The third support structure SS3′ may include a third support structure 146S_1 formed in contact with another third support structure 146S_2 that is adjacent to the third support structure 146S_1. The third support structure SS3′ may include SiCN or SiN. The third support structure SS3′ may include a material that may be easily brought into contact with TiN.

When a distance from a surface of the third support structure 146S_1 that is in contact with a lower electrode LE to a point of the third support structure 146S_1 that is farthest from the substrate 110 is defined as the height of the third support structure 146S_1, the height of the third support structure 146S_1 may be the same as the height the third support structure 146S_2.

Because the third support structure SS3′ has a spherical shape as described above, the third support structure SS3′ may not be easily separated from the lower electrodes LE and may thus be more stable.

According to the first to third support structures SS1, SS2, SS3, and SS3′ of the inventive concepts, structural stability may be guaranteed between the first to third supporting structures SS1, SS2, SS3, and SS3′ and the integrated circuit semiconductor device 100 while reducing a contact area between the lower electrodes LE and the third support structure SS3 or SS3′, thereby widening a range in which the lower electrodes LE are usable and increasing the capacitance of the lower electrodes LE.

FIGS. 4A to 4G are cross-sectional views illustrating a method of fabricating an integrated circuit semiconductor device, according to some example embodiments.

For example, FIGS. 4A to 4G are cross-sectional views illustrating a method of fabricating the integrated circuit semiconductor device 100 described with reference to FIGS. 2 and 3A. In FIGS. 4A to 4G, 2, and 3A, like reference numerals denote like elements, and repeated descriptions thereof are omitted.

Referring to FIG. 4A, a lower structure 120 is formed on a substrate 110 in which active regions AC are defined by device isolation regions 112, and conductive regions 124 connected to the active regions AC through the lower structure 120 are formed. Thereafter, an insulating layer 126 are formed to cover the lower structure 120 and the conductive regions 124.

The insulating layer 126 may be used as an etch stop layer in a subsequent process. The insulating layer 126 may include an insulating material having etch selectivity with respect to the lower structure 120. In some example embodiments, the insulating layer 126 may include a silicon nitride layer, a silicon carbonitride layer, a boron-containing silicon nitride layer, or a combination thereof. The insulating layer 126 may include, for example, SiBN.

Referring to FIG. 4B, a mold structure MST is formed on the insulating layer 126. The mold structure MST may include a plurality of mold layers and a plurality of support layers. For example, the mold structure MST may include a first mold layer 132, a first support layer 142, a second mold layer 134, a second support layer 144, a third mold layer 136, and a third support layer 146 that are sequentially stacked on the insulating layer 126.

The first mold layer 132, the second mold layer 134, and the third mold layer 136 may each include a material that has a relatively high etch rate with respect to an etchant containing ammonium fluoride (NH₄F), hydrofluoric acid (HF), and water, and is thus removable through a lift-off process using the etchant. In some example embodiments, each of the first mold layer 132, the second mold layer 134, and the third mold layer 136 may include an oxide layer, a nitride layer, or a combination thereof. However, the material of the first mold layer 132, the second mold layer 134, and the third mold layer 136 is not limited to the materials listed above, and various modifications and changes may be made within the scope of the inventive concepts. In addition, the stacking order of the mold structure MST is not limited to the order illustrated in FIG. 4B, and various modifications and changes may be made within the scope of the inventive concepts.

The first support layer 142 and the second support layer 144 may include a silicon carbonitride layer, a boron-containing silicon nitride layer, or a combination thereof. In some example embodiments, the first support layer 142 and the second support layer 144 may include the same material. In some example embodiments, the first support layer 142 and the second support layer 144 may include the same material as the third support layer 146. In some example embodiments, the first support layer 142 and the second support layer 144 may include different materials.

In some examples, each of the first support layer 142 and the second support layer 144 may include a silicon carbonitride layer. In other examples, the first support layer 142 may include a silicon carbonitride layer and the second support layer 144 may include a boron-containing silicon nitride layer. In embodiments, however, the materials of the first support layer 142 and the second support layer 144 are not limited to the materials listed above, and various modifications and changes may be made within the scope of the inventive concepts.

In some example embodiments, the first support layer 142, the second support layer 144, and the third support layer 146 may have thickness uniformity controlled by adjusting a deposition rate, a deposition gas, or deposition process parameters when the first support layer 142, the second support layer 144, and the third support layer 146 are respectively deposited on the first mold layer 132, the second mold layer 134, and the third mold layer 136.

Referring to FIG. 4C, a mask pattern MP is formed on the mold structure MST, and then, a plurality of holes BH are formed by anisotropically etching the mold structure MST using the mask pattern MP as an etch mask and the insulating layer 126 as an etch stop layer. The mask pattern MP may include a nitride layer, an oxide layer, a polysilicon layer, a photoresist layer, or a combination thereof.

As a result, a mold structure pattern MSP defining the holes BH may be obtained. The mold structure pattern MSP may include a first mold pattern 132P, a first support pattern 142P, a second mold pattern 134P, a second support pattern 144P, a third mold pattern 136P, and a third support pattern (upper support pattern) 146P.

The process of forming the holes BH may further include a process of wet-processing the result obtained by anisotropically etching the mold structure MST. While the mold structure MST is anisotropically etched and then wet-processed, portions of the insulating layer 126 may be etched together, thereby obtaining an insulating pattern 126P having a plurality of openings 126H through which the conductive regions 124 are exposed. For example, an etchant including a diluted sulfuric acid peroxide (DSP) solution may be used in the process of wet-processing the result obtained by anisotropically etching the mold structure MST.

Referring to FIG. 4D, after removing the mask pattern MP, a conductive layer 150 is formed on the resultant structure shown in FIG. 4C. The conductive layer 150 may be formed to fill the holes BH. The conductive layer 150 may include a metal layer, a conductive metal oxide layer, a conductive metal nitride layer, a conductive metal oxynitride layer, or a combination thereof.

In some example embodiments, the conductive layer 150 may include titanium (Ti), titanium oxide, titanium nitride, titanium oxynitride, cobalt (Co), cobalt oxide, cobalt nitride, cobalt oxynitride, niobium (Nb), niobium oxide, niobium nitride, niobium oxynitride, tin (Sn), tin oxide, tin nitride, tin oxynitride, or a combination thereof. For example, the conductive layer 150 may include TIN, CON, NbN, SnO₂, or a combination thereof, but is not limited thereto. The conductive layer 150 may be formed through a chemical vapor deposition (CVD) process, a plasma-enhanced CVD (PECVD) process, a metal organic CVD (MOCVD) process, or an atomic layer deposition (ALD) process.

Referring to FIG. 4E, a portion of the conductive layer 150 is removed through an etch-back process or a chemical mechanical polishing (CMP) process until an upper surface of the upper support pattern 146P that is the uppermost layer of the mold structure pattern MSP is exposed in the resultant structure shown in FIG. 4D. As a result, portions of the conductive layer 150 remaining in the holes BH (refer to FIG. 4D) may form a plurality of lower electrodes LE.

Referring to FIG. 4F, a plurality of upper holes UH are formed by removing portions of the second support pattern 144P, and then the second mold pattern 134P is removed in a wet manner through the upper holes UH.

Thereafter, a plurality of lower holes LH are formed by removing portions of the first support pattern 142P through the upper holes UH, and then, an upper surface of the insulating pattern 126P may be exposed by removing the first mold pattern 132P in a wet manner through the lower holes LH. Each of the upper holes UH and the lower holes LH may have a planar shape as illustrated with reference to FIG. 2.

As a result, sidewalls of the lower electrodes LE formed in the upper holes UH and the lower holes LH between the first support pattern 142P, the second support pattern 144P, and the upper support pattern 146P are exposed.

In addition, the first support pattern 142P, the second support pattern 144P, and the upper support pattern 146P remain between the lower electrodes LE. Therefore, the upper support pattern 146P may form a third support structure SS3, the second support pattern 144P may form a second support structure SS2, and the first support pattern 142P may form a first support structure SS1.

Referring to FIG. 4G, a dielectric layer 160 is formed to cover exposed surfaces of the lower electrodes LE that are shown in FIG. 4F. An ALD process may be used to form the dielectric layer 160. The dielectric layer 160 may include HfO₂, ZrO₂, Al₂O₃, La₂O₃, Ta₂O₃, Nb₂O₅, CeO₂, TiO₂, GeO₂, or a combination thereof but is not limited thereto.

Then, as shown in FIG. 3A, an upper electrode UE covering the dielectric layer 160 may be formed, thereby fabricating the integrated circuit semiconductor device 100 including capacitors CP1. The upper electrode UE may be formed through a CVD process, an MOCVD process, a physical vapor deposition (PVD) process, or an ALD process.

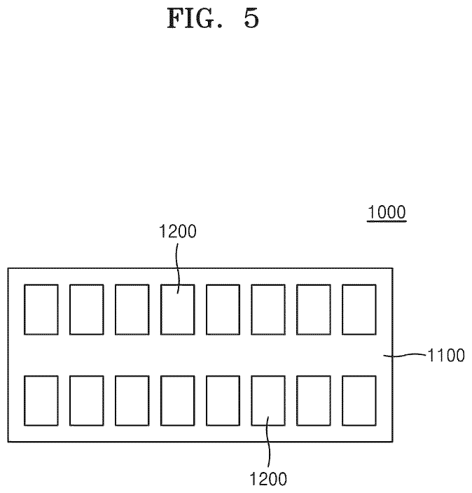

FIG. 5 is a plan view illustrating a memory module 1000 including an integrated circuit semiconductor device, according to some example embodiments.

For example, the memory module 1000 may include a printed circuit board 1100 and a plurality of semiconductor packages 1200. The semiconductor packages 1200 may each include the integrated circuit semiconductor device 100 of some example embodiments described above.

The memory module 1000 of the inventive concepts may be a simple in-lined memory module (SIMM) in which the semiconductor packages 1200 are mounted on only one side of the printed circuit board 1100, or may be a dual in-lined memory module (DIMM) in which the semiconductor packages 1200 are mounted on both sides of the printed circuit board 1100 In addition, the memory module 1000 of the inventive concepts may be a fully buffered DIMM (FBDIMM) having an advanced memory buffer (AMB) through which external signals are provided to the semiconductor packages 1200.

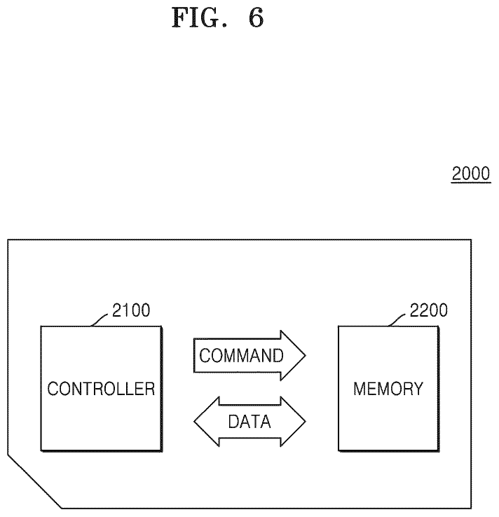

FIG. 6 is a schematic view illustrating a memory card 2000 including an integrated circuit semiconductor device according to some example embodiments.

For example, in the memory card 2000, a controller 2100 and a memory 2200 may be arranged to exchange electrical signals with each other. For example, when the controller 2100 issues a command, the memory 2200 may transmit data.

The memory 2200 may include the integrated circuit semiconductor device 100 according to some example embodiments described above. Examples of the memory card 2000 include various types of memory cards, such as a Memory Stick card, a Smart Media (SM) card, a Secure Digital (SD) card, a mini-SD card, and a MultiMedia Card (MMC).

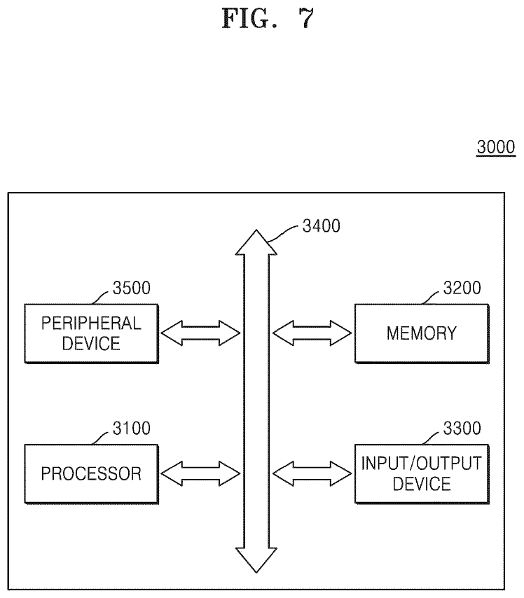

FIG. 7 is a schematic view illustrating a system 3000 including an integrated circuit semiconductor device, according to some example embodiments.

For example, in the system 3000, a processor 3100, a memory 3200, and an input/output device 3300 may communicate data with each other through a bus 3400. The memory 3200 of the system 3000 may include random access memory (RAM) and read only memory (ROM). That system 3000 may also include a peripheral device 3500 such as a floppy disk drive or a compact disk read-only memory (CD-ROM) drive.

The memory 3200 may include the integrated circuit semiconductor device 100 of some example embodiments described above. The memory 3200 may store code and data for operations of the processor 3100. The system 3000 may be used in mobile phones, MP3 players, navigation systems, portable multimedia players (PMPs), solid state disks (SSDs), or household appliances.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

While the inventive concepts have been particularly shown and described with reference to embodiments thereof, it will be understood that various changes in form and details may be made therein without departing from the spirit and scope of the following claims.

What is claimed is:

1. An integrated circuit semiconductor device comprising:
lower electrodes on a substrate; and
a support structure supporting the lower electrodes around the lower electrodes,
the support structure comprising
a first support structure supporting lower portions of the lower electrodes;
a second support structure apart from the first support structure in a vertical direction perpendicular to the substrate and supporting middle portions of the lower electrodes; and
a third support structure apart from the second support structure in the vertical direction perpendicular to the substrate and supporting node portions of the lower electrodes,
each of the first support structure, the second support structure, and the third support structure comprising
a support pattern extending in a horizontal direction parallel to the substrate and surrounding the lower electrodes, the support pattern comprising holes through which the lower electrodes pass; and
additional holes formed through the support pattern.

2. The integrated circuit semiconductor device of claim 1, wherein the third support structure has a layered structure.

3. The integrated circuit semiconductor device of claim 2, wherein, in the layered structure, a SiCN layer and a SiN layer are sequentially stacked from below, or a SiN layer and a SiCN layer are sequentially stacked from below.

4. The integrated circuit semiconductor device of claim 1, wherein the third support structure completely covers upper surfaces of two lower electrodes connected to both ends of a node.

5. The integrated circuit semiconductor device of claim 1, wherein the additional holes cross each other between the lower electrodes.

6. The integrated circuit semiconductor device of claim 1, wherein a material of the lower electrodes has a work function of 5.4 eV or greater.

7. The integrated circuit semiconductor device of claim 5, wherein a material of the lower electrodes comprises TiN or TiSiN.

8. The integrated circuit semiconductor device of claim 1, wherein a surface of the support pattern comprises a flat surface that is parallel to the substrate.

9. An integrated circuit semiconductor device comprising:
lower electrodes on a substrate; and
a support structure supporting the lower electrodes around the lower electrodes,
the support structure comprising
a first support structure supporting lower portions of the lower electrodes;
a second support structure apart from the first support structure in a vertical direction perpendicular to the substrate and supporting middle portions of the lower electrodes; and
third support structures apart from the second support structure in the vertical direction perpendicular to the substrate and formed in a spherical shape on upper node portions of the lower electrodes,
each of the first support structure and the second support structure comprising
a support pattern extending in a horizontal direction parallel to the substrate and surrounding the lower electrodes, the support pattern comprising holes through which the lower electrodes pass; and
additional holes formed through the support pattern.

10. The integrated circuit semiconductor device of claim 9, wherein the third support structures comprise at least some third support structures that are adjacent to each other and in contact with each other.

11. The integrated circuit semiconductor device of claim 9, wherein the third support structures comprise SiCN or SiN.

12. The integrated circuit semiconductor device of claim 9, wherein a surface of the support pattern comprises a flat surface that is parallel to the substrate.

13. The integrated circuit semiconductor device of claim 9, wherein, based on distances from surfaces of the third support structures contacting the lower electrodes to points the third support structures are farthest from the substrate being defined as heights of the third support structures, the heights of adjacent third support structures are equal to each other.

14. The integrated circuit semiconductor device of claim 9, wherein the additional holes cross each other between the lower electrodes.

15. An integrated circuit semiconductor device comprising:
a plurality of lower electrodes arranged apart from each other on a substrate;
a third support structure at nodes of the plurality of lower electrodes in a horizontal direction parallel to the substrate;
a second support structure comprising a second support pattern extending in the horizontal direction parallel to the substrate, the second support pattern comprising a plurality of holes through which the plurality of lower electrodes pass and having a flat surface parallel to the substrate;
a first support structure comprising a first support pattern extending in the horizontal direction between the substrate and the second support structure, the first support pattern comprising a plurality of holes through which the plurality of lower electrodes pass and having a flat surface parallel to the substrate;
a dielectric layer in contact with the plurality of lower electrodes, the first support structure, and the second support structure; and
an upper electrode facing the plurality of lower electrodes with the dielectric layer therebetween.

16. The integrated circuit semiconductor device of claim 15, wherein the third support structure comprises a third support pattern comprising a plurality of holes through which the plurality of lower electrodes pass and having a flat surface parallel to the substrate.

17. The integrated circuit semiconductor device of claim 16, wherein the third support structure has a layered structure in which a SiCN layer and a SiN layer are sequentially stacked from below, or a SiN layer and a SiCN layer are sequentially stacked from below.

18. The integrated circuit semiconductor device of claim 16, wherein the third support structure completely covers upper surfaces of two lower electrodes connected to both ends of a node.

19. The integrated circuit semiconductor device of claim 15, wherein the third support structure has a spherical shape on upper node portions of the plurality of lower electrodes.

20. The integrated circuit semiconductor device of claim 19, wherein the third support structure comprises third support structures that are adjacent to each other and in contact with each other.
